(19) United States
(12) Patent Application Publication
(10) Pub. No.: US 2025/0261551 A1
(43) Pub. Date: Aug. 14, 2025

(54) DISPLAY DEVICE AND METHOD OF MANUFACTURING THE SAME

(71) Applicant: Samsung Display Co., Ltd., Yongin-si (KR)

(72) Inventors: Daewon CHOI, Yongin-si (KR); Daesoo KIM, Yongin-si (KR); Taesung KIM, Yongin-si (KR); Taesang PARK, Yongin-si (KR); Kyongchol LEE, Yongin-si (KR)

(21) Appl. No.: 18/980,031

(22) Filed: Dec. 13, 2024

(30) Foreign Application Priority Data
Feb. 8, 2024 (KR) 10-2024-0019862

(51) Int. Cl. H10K 59/88; H10K 59/12; H10K 59/122

(52) U.S. Cl. CPC H10K 59/88; H10K 59/1201; H10K 59/122

(57) ABSTRACT

A display device includes a substrate, a pixel circuit layer arranged on the substrate and including a thin-film transistor, a via insulating layer arranged on the pixel circuit layer and having a concave part, an auxiliary pattern arranged on the concave part of the via insulating layer, an etch stop layer arranged between the via insulating layer and the auxiliary pattern, and a light-emitting element arranged on the via insulating layer.

This application claims priority to Korean Patent Application No. 10-2024-0019862, filed on Feb. 8, 2024, and all the benefits accruing therefrom under 35 U.S.C. § 119, the content of which in its entirety is herein incorporated by reference.

### BACKGROUND

### 1. Field

The invention relates to a display device and, more particularly to a display device and a method of manufacturing the display device.

### 2. Description of the Related Art

Display devices display data visually and can be used as a display of small products, such as mobile phones, or as a display of large products, such as televisions.

A display device includes a plurality of pixels that receive an electrical signal and that emit light to display an image externally. Each of the plurality of pixels includes a light-emitting element, and for example, in the case of an organic light-emitting display, each pixel includes an organic light-emitting diode (OLED) as the light-emitting element.

### SUMMARY

One or more embodiments include a display device that has enhanced luminance and/or color deviation due to a viewing angle, while simultaneously having excellent light efficiency. However, this is merely illustrative, and the scope of the invention is not limited thereto.

According to one or more embodiments, a display device includes a substrate, a pixel circuit layer arranged on the substrate and including a thin-film transistor, a via insulating layer arranged on the pixel circuit layer and having a concave part, an auxiliary pattern arranged on the concave part of the via insulating layer, an etch stop layer arranged between the via insulating layer and the auxiliary pattern, and a light-emitting element arranged on the via insulating layer.

In an embodiment, a shape of the etch stop layer may correspond to a shape of the auxiliary pattern in a plan view.

In an embodiment, a side surface of the auxiliary pattern may be inclined from an upper surface of the concave part of the via insulating layer in a cross-section.

In an embodiment, the upper surface of the concave part of the via insulating layer may be substantially flat.

In an embodiment, the light-emitting element may include a first electrode disposed on the via insulating layer, a light-emitting layer disposed on the first electrode, and a second electrode disposed on the light-emitting layer, and the first electrode may include a first part arranged on an upper surface of the concave part of the via insulating layer, a second part arranged on a side surface of the concave part of the via insulating layer, and a third part arranged on a side surface of the auxiliary pattern.

In an embodiment, each of the second part and the third part of the first electrode may be inclined from the first part of the first electrode.

In an embodiment, the display device may further include a pixel-defining layer arranged on the first electrode and having a pixel opening that exposes the first part, the second part and the third part of the first electrode.

In an embodiment, the auxiliary pattern may have an island pattern shape or a ring shape.

In an embodiment, the etch stop layer and the auxiliary pattern may have different etch rates from each other.

In an embodiment, the auxiliary pattern may include an inorganic material.

According to one or more embodiments, a display device includes a substrate, a pixel circuit layer arranged on the substrate and including a thin-film transistor, a via insulating layer arranged on the pixel circuit layer and having a plurality of concave parts, auxiliary patterns respectively arranged on the plurality of concave parts of the via insulating layer, etch stop layers respectively arranged between the via insulating layer and the auxiliary patterns, and a first light-emitting element and a second light-emitting element each arranged on the via insulating layer and configured to emit pieces of lights having different colors, wherein the first light-emitting element and the second light-emitting element may be disposed to correspond to the plurality of concave parts.

In an embodiment, shapes of the etch stop layers respective correspond to the auxiliary patterns in a plan view.

In an embodiment, an auxiliary pattern disposed to correspond to the first light-emitting element from among the auxiliary patterns and an auxiliary pattern disposed to correspond to the second light-emitting element from among the auxiliary patterns may have different shapes from each other.

In an embodiment, each of the auxiliary patterns may have an island pattern shape or a ring shape.

In an embodiment, the auxiliary patterns may include an inorganic material.

In an embodiment, the etch stop layers and the auxiliary patterns may have different etch rates from each other.

According to one or more embodiments, a method of manufacturing a display device includes forming a pixel circuit layer including a thin-film transistor on a substrate, forming a via insulating layer having a concave part on the pixel circuit layer, forming an etch stop layer on the via insulating layer, forming a preliminary pattern on the etch top layer, etching a part of the preliminary auxiliary pattern to form an auxiliary pattern disposed on the concave part of the via insulating layer, etching a part of the etch stop layer to have a shape which corresponds to a shape of the auxiliary pattern in a plan view, and forming a light-emitting element on the auxiliary pattern, where the light-emitting element includes a first electrode, an intermediate layer, and a second electrode.

In an embodiment, a process of etching the preliminary auxiliary pattern may be a dry etching process.

In an embodiment, the etching of a part of the etch stop layer may be a wet etching process.

In an embodiment, an etch rate of the etch stop layer may be less than an etch rate of the preliminary auxiliary pattern.

### BRIEF DESCRIPTION OF THE DRAWINGS

The above and other aspects, features, and advantages of certain embodiments of the invention will be more apparent from the following description taken in conjunction with the accompanying drawings, in which:

FIG. 1 is a perspective view schematically illustrating a display device, according to an embodiment;

FIG. 2 illustrates a display element provided in a pixel and a pixel circuit connected thereto, of a display device, according to an embodiment;

FIG. 3 is a plan view of a part of a pixel arrangement in a display area of the display device, according to an embodiment;

FIG. 4 is a cross-sectional view schematically illustrating an arrangement of auxiliary patterns in a region corresponding to one pixel, according to an embodiment;

FIG. 5A is a schematic cross-sectional view of a display device, taken along a line I-I′ of FIG. 4, according to an embodiment;

FIG. 5B is a schematic cross-sectional view of a display device, taken along a line I-I′ of FIG. 4, according to an embodiment;

FIG. 6 is a cross-sectional view schematically illustrating an arrangement of auxiliary patterns in a region corresponding to one pixel, according to an embodiment;

FIG. 7 is a cross-sectional view schematically illustrating an arrangement of auxiliary patterns in a region corresponding to one pixel, according to an embodiment;

FIG. 8 is a cross-sectional view schematically illustrating a display device, according to an embodiment; and

FIG. 9 is a cross-sectional view illustrating a method of manufacturing a display device, according to an embodiment;

FIG. 10 is a cross-sectional view illustrating a method of manufacturing a display device, according to an embodiment;

FIG. 11 is a cross-sectional view illustrating a method of manufacturing a display device, according to an embodiment;

FIG. 12 is a cross-sectional view illustrating a method of manufacturing a display device, according to an embodiment;

FIG. 13 is a cross-sectional view illustrating a method of manufacturing a display device, according to an embodiment;

FIG. 14 is a cross-sectional view illustrating a method of manufacturing a display device, according to an embodiment; and

FIG. 15 is a cross-sectional view illustrating a method of manufacturing a display device, according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since various modifications and various embodiments are possible, specific embodiments are illustrated in the drawings and described in detail in the detailed description. Effects and features of the invention, and a method of achieving them will be apparent with reference to embodiments described below in detail in conjunction with the drawings. However, the invention is not limited to the embodiments disclosed herein, but may be implemented in a variety of forms.

Hereinafter, embodiments will be described in detail with reference to the accompanying drawings, and the same or corresponding components are denoted by the same reference numerals, and the same reference numerals are assigned and redundant explanations will be omitted.

In the following embodiments, the terms “first” and “second”, etc. were used for the purpose of distinguishing one element from other elements, not in a limited sense.

In the following embodiments, the singular expression includes a plurality of expressions unless the context is clearly different.

In the following embodiments, the terms such as “comprising” or “having” are meant to be the features described in the specification, or the elements that are present, and the possibility of one or more other features or elements will be added, and is not excluded in advance.

In the following embodiments, when a portion such as a layer, a region, an element or the like is on other portions, this is not only when the portion is on other elements, but also when other elements are interposed therebetween.

In the drawings, for convenience of explanation, the sizes of elements may be exaggerated or reduced. For example, since the size and thickness of each component shown in the drawings are arbitrarily indicated for convenience of explanation, the invention is not necessarily limited to the illustration.

In the specification, in the case where some embodiments may be implemented in the specification, a specific process order may be performed differently from the order described. For example, two processes described in succession may be substantially performed at the same time, or in an opposite order to an order to be described.

In the specification, ‘A and/or B’ means A, B, or A and B. In addition, ‘at least one of A and B’ is A, B, or A and B.

In the following embodiments, when a layer, a region, a component, etc. are connected to each other, the layer, the region, and the components are directly connected to each other and/or the layer, the region, and the components may be indirectly connected to each other with other layers, other regions and other components interposed between the layer, the region, and the components. For example, when a layer, a region, a component, etc. are electrically connected to each other in the specification, the layer, the region, the component, etc. are directly electrically connected to each other, and/or the layer, the region, the component, etc. are indirectly electrically connected to each other with other layers, other regions and other components interposed between the layer, the region, and the components.

The x-axis, the y-axis, and the z-axis are not limited to three axes on a Cartesian coordinate system and may be interpreted in a broad sense including the same. For example, the x-axis, the y-axis, and the z-axis may be perpendicular to each other, but may refer to different directions that are not orthogonal to each other.

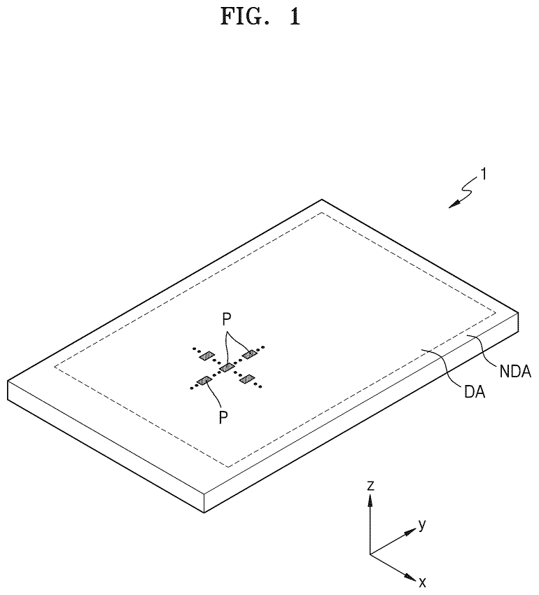

FIG. 1 is a perspective view schematically illustrating a display device 1, according to an embodiment.

In an embodiment, the display device 1 may be a device for displaying a moving image or still image and may be used for a display screen of various products such as portable devices, for example, a mobile phone, a smart phone, a tablet personal computer (PC), a mobile communication terminal, an electronic notebook, an electronic book, a portable multimedia player (PMP), a navigation system, and an ultra mobile PC (PC), televisions, laptop computers, monitors, billboards, Internet of Things (IOT), and the like.

In an embodiment, the display device 1 may be used for a wearable device such as a smart watch, a watch phone, a glasses type display, or a head mounted display (HMD).

In an embodiment, the display device 1 may be used as an instrument panel of a vehicle, and a center information display (CID) disposed on a center fascia or a dashboard of a vehicle, a room mirror display for replacing a side mirror of a vehicle, and a display disposed on the rear surface of the front seat or middle row seats in a vehicle with more than three rows of seats.

In an embodiment and referring to FIG. 1, the display device 1 may include a display area DA and a non-display area NDA disposed outside of the display area DA. A plurality of pixels P including a display clement may be arranged in the display area DA, and the display device 1 may provide an image using light emitted from the plurality of pixels P arranged in the display area DA. The non-display area NDA may be an area in which no display elements are arranged, and the display area DA may be entirely surrounded by the non-display area NDA.

The display device 1 may have various shapes, and for example, may have a shape of a rectangular plate with two parallel sides. In FIG. 1, for convenience of explanation, the display device 1 has a rectangular shape with a pair of long sides and a pair of short sides. However, the shape of the display device 1 is not limited thereto, and the display device 1 may have various shapes. For example, the display device 1 may have various shapes, such as a closed polygonal shape with straight sides, a circular shape, an elliptical shape or the like with curved sides, a semi-circular shape, a semi-elliptical shape or the like with straight and curved sides.

In an embodiment, the display area DA may be a portion in which an image is displayed, and the plurality of pixels P may be arranged in the display area DA. Each of the plurality of pixels P may include a display element such as an organic light-emitting diode, where each pixel P may emit red, green, blue or white light, for example.

In the display area DA, a certain image may be displayed through light emitted from the pixels P. In the present specification, the pixel P may be defined as a light-emitting area in which light of any one of red, green, blue and white is emitted as described above.

In an embodiment, the non-display area NDA may be an area in which the pixels P are not arranged and no image is provided. A printed circuit board including a power supply wiring for driving the pixels P, and a driving circuit portion, or terminals to which a driver integrated circuit (IC) is connected, may be arranged in the non-display area NDA.

Hereinafter, the display device 1, according to an embodiment, may be an organic light-emitting display device, an inorganic light-emitting display or an inorganic electroluminescent (EL) display device, or a quantum dot light-emitting display. For example, a light-emitting layer of the light-emitting element of the display device 1 may include an organic material or an inorganic material. In another embodiment, quantum dots may be placed on a path of light emitted from the light-emitting layer.

FIG. 1 schematically illustrates the display device 1 having a flat shape, and the shape of the display device 1 is not limited thereto. For example, the display device 1 may include a stereoscopic display surface or a curved display surface. When the display device 1 includes a curved display surface, the display device 1 may have various shapes, such as a flexible display device, a foldable display device, a rollable display device, and the like.

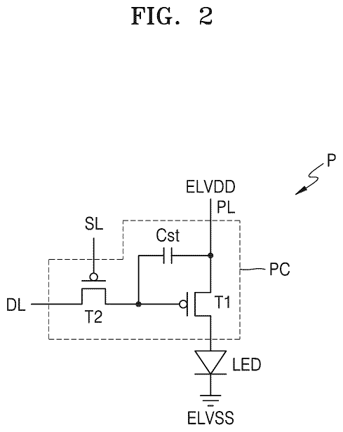

FIG. 2 illustrates a display element provided in a pixel P and a pixel circuit PC connected to the display element, according to an embodiment.

In an embodiment and referring to FIG. 2, a light-emitting element LED that is a display clement may be connected to the pixel circuit PC. The pixel circuit PC may include a first thin-film transistor T1, a second thin-film transistor T2, and a storage capacitor Cst. The light-emitting clement LED may emit red, green, or blue light, for example, or may emit red, green, blue, or white light.

In an embodiment, the second thin-film transistor T2 may be a switching thin-film transistor which may be connected to the scan line SL and the data line DL, and which may be configured to transmit a data voltage input to the first thin-film transistor T1 from the data line DL in response to a switching voltage input from the scan line SL. The storage capacitor Cst may be connected to the second thin-film transistor T2 and the driving voltage line PL and may store a voltage corresponding to a potential difference between a voltage transmitted from the second thin-film transistor T2 and a first power supply voltage ELVDD supplied to the driving voltage line PL.

In an embodiment, the first thin-film transistor T1 may be a driving thin-film transistor which may be connected to the driving voltage line PL and the storage capacitor Cst, and which may control a driving current flowing through the light-emitting element LED from the driving voltage line PL in response to a voltage value stored in the storage capacitor Cst. The light-emitting clement LED may emit light having certain luminance using the driving current. A first electrode (e.g., an anode) of the light-emitting element LED may be connected to the pixel circuit PC, and a second electrode (e.g., a cathode) of the light-emitting element LED may be supplied with a second power supply voltage ELVSS.

FIG. 2 illustrates that the pixel circuit PC includes two thin-film transistors and one storage capacitor. However, in another embodiment, the number of thin-film transistors or the number of storage capacitors may be variously changed according to the design of the pixel circuit PC.

In an embodiment, each of the first thin-film transistor T1 and the second thin-film transistor T2 may be provided as a p-channel metal oxide semiconductor field effect transistor (MOSFET) (PMOS) or an n-channel MOSFET (NMOS). IN another embodiment, a part of a plurality of transistors of the pixel circuit PC may be provided as PMOSs, and the other part thereof may be provided as NMOSs.

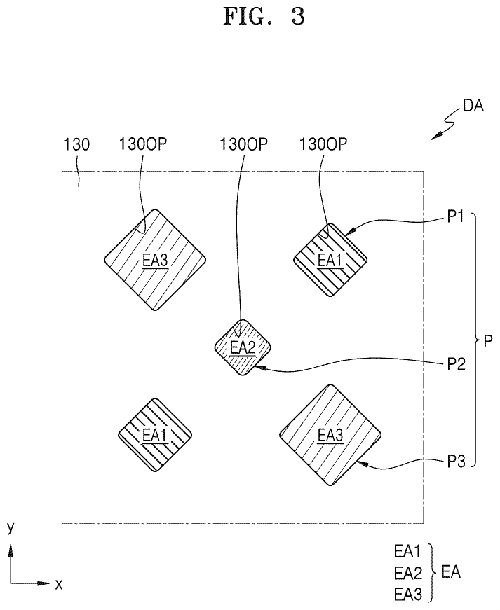

FIG. 3 is a plan view of a part of pixel arrangement in the display area DA of the display device 1, according to an embodiment.

In an embodiment and referring to FIG. 3, the display device 1 may include a plurality of pixels P, where the plurality of pixels P may include a first pixel P1, a second pixel P2, and a third pixel P3, which produce different colors. For example, the first pixel P1 may emit red light, the second pixel P2 may emit green light, and the third pixel P3 may emit blue light. However, embodiments are not limited thereto. For example, in another embodiment, various modifications may be possible, such as the first pixel emitting blue light, the second pixel P2 emitting green light, and the third pixel P3 emitting red light.

In an embodiment, the first pixel P1, the second pixel P2, and the third pixel P3 may have polygonal shapes. For example, the first pixel P1, the second pixel P2, and the third pixel P3 may have rectangular shapes. In this embodiment, the polygon includes a polygon in the form of round vertexes, while in another embodiment, the first pixel P1, the second pixel P2, and the third pixel P3 may have circular or elliptical shapes.

Additionally, the first pixel P1, the second pixel P2, and the third pixel P3 may have different sizes from each other. For example, the area of the second pixel P2 may be less than the area of the first pixel P1 and the third pixel P3, and the area of the third pixel P3 may be greater than the area of the first pixel P1. In another embodiment, various modifications are possible, such as the first pixel P1, the second pixel P2, and the third pixel P3 having substantially the same size.

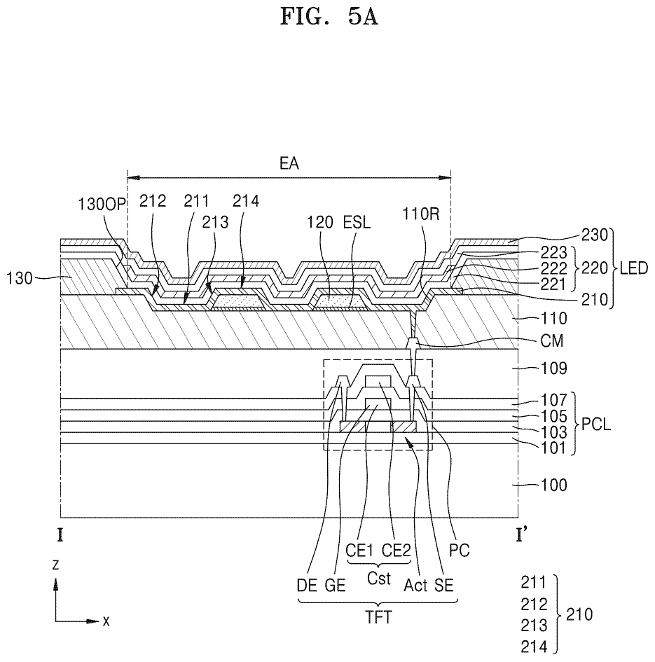

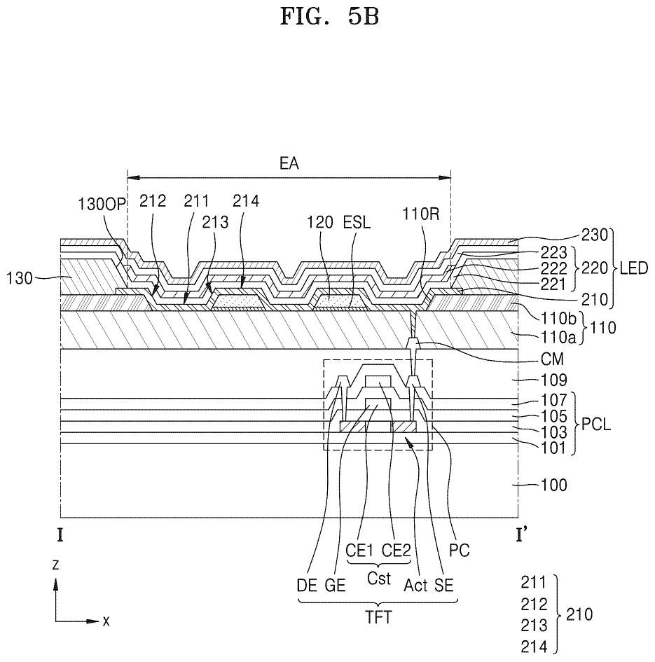

In the present specification, the size of each of the plurality of pixels P also means the size of an emission area EA of the display element that implements each pixel, and the emission area EA may be defined by a pixel opening 130OP of the pixel-defining layer 130 that will be described later with reference to FIG. 5A. For example, the sizes of the first pixel P1, the second pixel P2, and the third pixel P3 also mean the sizes of the first emission area EA1, the second emission area EA2 and the third emission area EA3 of the display element that implements each pixel, and each of the emission areas EA1, EA2, and EA3 may be defined by the pixel opening 130OP of the pixel-defining layer 130.

In an embodiment, the pixel opening 130OP of the pixel-defining layer 130 may have a polygonal shape in a plan view. For example, the pixel opening 130OP of the pixel-defining layer 130 may have a polygonal shape in a plan view. In another embodiment, the pixel opening 130OP of the pixel-defining layer 130 may have a circular or elliptical shape in a plan view. That is, the emission areas EA1, EA2, and EA3 defined by the pixel opening 130OP of the pixel-defining layer 130 may be changed into various shapes such as a polygonal shape, a circular shape, an elliptical shape, and the like in a plan view.

In an embodiment and as shown in FIG. 3, the first pixel P1, the second pixel P2, and the third pixel P3 may be arranged in the pixel arrangement of a pentile™ structure, but this is exemplary, and the invention are not limited thereto. For example, the first pixel P1, the second pixel P2, and the third pixel P3 may be arranged in various pixel arrangement structures such as a stripe structure, a mosaic structure, a delta structure, and the like.

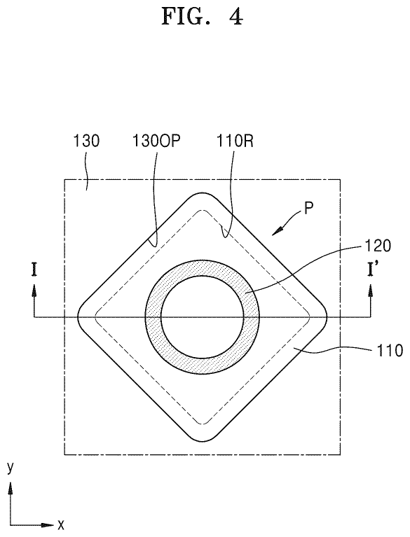

FIG. 4 is a cross-sectional view schematically illustrating an arrangement of an auxiliary pattern 120 in a region corresponding to one pixel P, according to an embodiment. FIG. 5A is a schematic cross-sectional view of the display device 1 taken along a line I-I′ of FIG. 4, according to an embodiment.

In an embodiment and referring to FIGS. 4 and 5A, the display device 1 may include a substrate 100, a pixel circuit layer PCL, first and second via insulating layers 109 and 110, and a light-emitting element LED. In an embodiment, the display device 1 may further include a pixel-defining layer 130.

In an embodiment, the substrate 100 may include a glass or polymer resin. For example, the polymer resin may include polyethersulfone, polyacrylate, polyether imide, polyethylene naphthalate, polyethylene terephthalate, polyphenylene sulfide, polyarylate, polyimide, polycarbonate, or cellulose acetate propionate. The substrate 100 including the polymer resin may have flexible, rollable or bendable characteristics. Additionally, the substrate 100 may have a multi-layered structure including a layer including a polymer resin and an inorganic layer.

In an embodiment, the pixel circuit layer PCL may be arranged on the substrate 100, where the pixel circuit layer PCL may include a pixel circuit PC and insulating layers. The pixel circuit PC may include a transistor and a storage capacitor described above with reference to FIG. 2. In an embodiment, FIG. 5A illustrates a thin-film transistor TFT and a storage capacitor provided in the pixel circuit PC.

The pixel circuit layer PCL may include a buffer layer 101, a first gate insulating layer 103, a second gate insulating layer 105, an interlayer insulating layer 107, and a thin-film transistor TFT.

The buffer layer 101 may be disposed on the substrate 100, may reduce or prevent penetration of foreign substances, moisture or external air from the lower portion of the substrate 100, and may provide a flat surface for the substrate 100. The buffer layer 101 may include an inorganic material such as oxide or nitride, an organic material, or an organic/inorganic composite material, and may have a single layer or multi-layered structure of the inorganic material and the organic material. A barrier layer (not shown) for preventing penetration of external air may be further disposed between the substrate 100 and the buffer layer 101. The buffer layer 101 may also include silicon oxide (SiO₂) or silicon nitride (SiNx).

In an embodiment, thin-film transistors TFT may be arranged above the buffer layer 101, where each of the thin-film transistors TFT may include a semiconductor layer Act, a gate electrode GE, a drain electrode DE, and a source electrode SE. The thin-film transistors TFT may be electrically connected to the light-emitting element LED and may drive the LED.

The semiconductor layer Act may be arranged on the buffer layer 101 and may include an oxide semiconductor and/or a silicon semiconductor. When the semiconductor layer Act includes an oxide semiconductor, the semiconductor layer Act may include oxide including at least one material selected from the group consisting of indium (In), gallium (Ga), stanum (Sn), zirconium (Zr), vanadium (V), hafnium (Hf), cadmium (Cd), germanium (Ge), chromium (Cr), titanium (Ti), and zinc (Zn). For example, the semiconductor layer Act may be an InSnZnO (ITZO) semiconductor layer, an InGaZnO (IGZO) semiconductor layer, or the like. When the semiconductor layer Act includes a silicon semiconductor, the semiconductor layer Act may include, for example, amorphous silicon or low temperature poly-silicon (LTPS).

The gate electrode GE may be arranged on the semiconductor layer Act with the first gate insulating layer 103 disposed therebetween. The gate electrode GE may be arranged to overlap a channel region of the semiconductor layer Act and may include a low-resistance metal material. For example, the gate electrode GE may have a single layer structure or a multi-layered structure including at least one metal selected from the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The gate electrode GE may also be connected to a gate line for applying an electrical signal to the gate electrode GE.

The first gate insulating layer 103 may be arranged on the buffer layer 101 and may be arranged between the semiconductor layer Act and the gate electrode GE. The first gate insulating layer 103 may include, for example, an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

A second gate insulating layer 105 may be arranged on the first gate insulating layer 103 and may be provided to cover the gate electrode GE. The second gate insulating layer 105 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ), similarly to the first gate insulating layer 103.

A second electrode CE2 of the storage capacitor Cst may be arranged above the second gate insulating layer 105. In an embodiment, the second capacitor electrode CE2 may overlap the gate electrode GE. The gate electrode GE, and the second capacitor electrode CE2, which overlap each other with the second gate insulating layer 105 disposed therebetween, may form the storage capacitor Cst. That is, the gate electrode GE may function as a first capacitor electrode CE1 of the storage capacitor Cst. In this way, the storage capacitor Cst and the thin-film transistor TFT may overlap each other. In another embodiment, the storage capacitor Cst and the thin-film transistor TFT may not overlap each other.

An interlayer insulating layer 107 may be arranged on the second gate insulating layer 105 and may be provided to cover the second capacitor electrode CE2. The interlayer insulating layer 107 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The interlayer insulating layer 105 may have a single layer or a multi-layered structure including the above-described inorganic insulating materials.

In an embodiment, each of the source electrode SE and the drain electrode DE may be arranged on the interlayer insulating layer 107, where the source electrode SE and the drain electrode DE may be electrically connected to the semiconductor layer Act via a contact hole formed in the first gate insulating layer 103, the second gate insulating layer 105, and the interlayer insulating layer 107. The source electrode SE and the drain electrode DE may include good conductive materials. At least one of the source electrode SE and the drain electrode DE may include a conductive material including Mo, Al, Cu, Ti, or the like, and may have a multi-layered or single layer structure including the materials described above. In an embodiment, at least one of the source electrode SE and the drain electrode DE may have a multi-layered structure of Ti/Al/Ti.

In an embodiment, a first via insulating layer 109 and a second via insulating layer 110 may be arranged on the pixel circuit layer PCL. The first via insulating layer 109 and the second via insulating layer 110 may be arranged on the source electrode SE and the drain electrode DE. The first via insulating layer 109 and the second via insulating layer 110 may planarize an upper surface of the pixel circuit PC including the thin-film transistor TFT to planarize a surface on which the light-emitting element LED is disposed, where the first via insulating layer 109 and the second via insulating layer 110 may be referred to as a first planarization insulating layer and a second planarization insulating layer, respectively. In FIG. 5A, the display device 1 includes two via insulating layers. However, the invention is not limited thereto, and, in another embodiment, the display device 1 may include a single via insulating layer or two or more multi-layered via insulating layers.

In an embodiment, the first via insulating layer 109 may be arranged on the interlayer insulating layer 107 and may be arranged on the source electrode SE and the drain electrode DE. A connection electrode CM may be arranged above the first via insulating layer 109. The connection electrode CM may be arranged between the thin-film transistor TFT and the light-emitting element LED and may electrically connect the thin-film transistor TFT and the light-emitting element LED to each other. The second via insulating layer 110 may be arranged on the first via insulating layer 109. The second via insulating layer 110 may be arranged on the connection electrode CM.

Each of the first via insulating layer 109 and the second via insulating layer 110 may be an organic insulating layer including an organic material. Each of the first via insulating layer 109 and the second via insulating layer 110 may include an organic insulating material such as general common-use polymer such as photosensitive polyimide (PSPI), polyimide, polystyrene (PS), polycarbonate (PC), benzocyclobutene (BCB), hexamethyldisiloxane (HMDSO), polymethylmethacrylate (PMMA) or polystyrene (PS), a polymer derivative having a phenol-based group, acryl-based polymer, imide-based polymer, aryl ether-based polymer, amide-based polymer, fluorine-based polymer, p-xylene-based polymer, vinyl alcohol-based polymer, and a blend thereof.

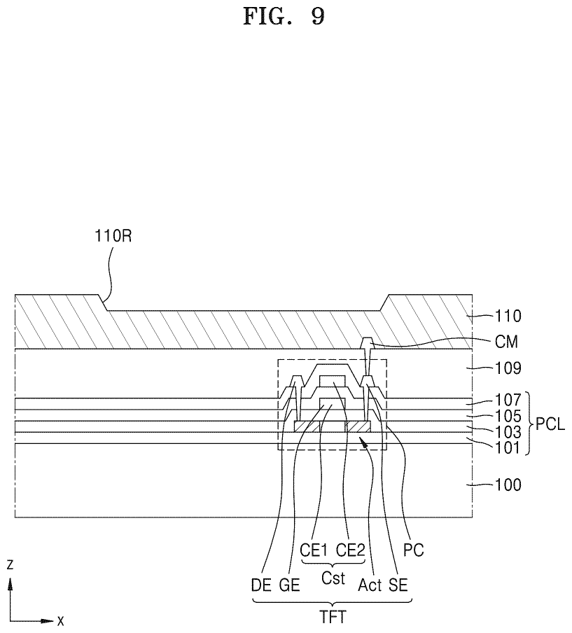

In an embodiment, the second via insulating layer 110 may have a concave part 110R and may be a part having a concave shape directed toward the substrate 100. The concave part 110R of the second via insulating layer 110 may be a part formed by removing a part of the second via insulating layer 110, as will be described later with reference to FIG. 9. In an embodiment, as shown in FIG. 4, the area of the concave part 110R of the second via insulating layer 110 may be less than the area of the emission area EA defined by the pixel opening 130OP of the pixel-defining layer 130.

In an embodiment, an upper surface of the concave part 110R of the second via insulating layer 110 may be substantially flat and a side surface of the concave part 110R of the second via insulating layer 110 may be an inclined surface from the upper surface of the concave part 110R.

In an embodiment, the display device 1 may further include an auxiliary pattern 120 arranged on the concave part 110R of the second via insulating layer 110, where the auxiliary pattern 120 may be arranged in the emission area EA. The auxiliary pattern 120 may have an inclined surface in a cross-section. For example, the inclined surface of the auxiliary pattern 120 may be inclined from the upper surface of the second via insulating layer 110 (for example, the upper surface of the concave part 110R of the second via insulating layer 110). For example, the auxiliary pattern 120 may have a tapered shape.

In an embodiment, the auxiliary pattern 120 may have a ring shape in a plan view. In FIG. 4, the auxiliary pattern 120 has a circular ring shape, but the invention is not limited thereto. For example, the shape of the auxiliary pattern 120 may be variously changed into a polygonal ring shape, a polygonal ring shape with round corners, an elliptical ring shape, and the like. The shape of the auxiliary pattern 120 is not limited to the ring shape and may be variously changed such as having an island pattern shape.

In an embodiment, the auxiliary pattern 120 may include a material that may be etched by a dry etching process. The auxiliary pattern 120 may include an inorganic material, for example, silicon nitride (SiNx), silicon oxynitride (SiON), silicon oxide (SiOx).

In an embodiment, the display device 1 may further include an etch stop layer ESL arranged between the second via insulating layer 110 and the auxiliary pattern 120, where the etch stop layer ESL and the auxiliary pattern 120 may have different etch rates from each other.

In an embodiment, a shape of the etch stop layer ESL may correspond to a shape of the auxiliary pattern 120 in a plan view. The etch stop layer ESL may be disposed to overlap the auxiliary pattern 120 and may be arranged only between the second via insulating layer 110 and the auxiliary pattern 120. For example, the etch stop layer ESL may be arranged on the concave part 110R of the second via insulating layer 110 and may cover an upper surface of the etch stop layer ESL.

In an embodiment, the etch stop layer ESL may include a material that may be etched by a wet etching process. In an embodiment, the etch stop layer ESL may include a material having a different etch rate from an etch rate of the auxiliary pattern 120. For example, while a dry etching process is performed, the etch rate of the etch stop layer ESL may be less than the etch rate of the auxiliary pattern 120 and may include IZO, IZGO or ITO.

In an embodiment, the light-emitting element LED may be arranged on the second via insulating layer 110, where the light-emitting element LED may be electrically connected to the pixel circuit PC which is arranged between the substrate 100 and the light-emitting element LED in a direction (e.g., a z direction) that is perpendicular to the upper surface of the substrate 100.

The light-emitting element LED may have a stack structure of a first electrode 210, an intermediate layer 220, and a second electrode 230. The first electrode 210 of the light-emitting clement LED may be an anode, and the second electrode 230 of the light-emitting element LED may be a cathode, but the invention is not limited thereto. For example, in an embodiment, the light-emitting element LED may be an inverted light-emitting element having the first electrode 210 as a cathode and the second electrode 230 as an anode. Hereinafter, for convenience of explanation, an embodiment of a light-emitting element having the first electrode 210 as an anode and the second electrode 230 as a cathode will be described.

In an embodiment, the first electrode 210 may be arranged on the second via insulating layer 110, where the first electrode 210 may be electrically connected to the thin-film transistor TFT provided at the pixel circuit PC. For example, the first electrode 210 may be electrically connected to the thin-film transistor TFT via the connection electrode CM. For example, the first electrode 210 may be electrically connected to the connection electrode CM via a contact hole of the second via insulating layer 110, and the connection electrode CM may be electrically connected to the thin-film transistor TFT via a contact hole of the first via insulating layer 109.

In an embodiment, the first electrode 210 may include a first part 211 disposed on the upper surface of the concave part 110R of the second via insulating layer 110, a second part 212 disposed on the side surface of the concave part 110R of the second via insulating layer 110, a third part 213 disposed on the side surface of the auxiliary pattern 120, and a fourth part 214 disposed on the upper surface of the auxiliary pattern 120.

In a comparative example in which the etch stop layer ESL is not formed between the auxiliary pattern 120 and the second via insulating layer 110, a part of the concave part 110R of the second via insulating layer 110 may be over-etched in an etching process of forming the auxiliary pattern 120. For example, the upper surface of the concave part 110R of the second via insulating layer 110 according to the comparative example may be over-etched in a region where the concave part 110R of the second via insulating layer 110 does not overlap the auxiliary pattern 120, and may be relatively concave, and may be relatively convex in a region where the concave part 110R of the second via insulating layer 110 overlaps the auxiliary pattern 120, and thus may not be flat. For example, the concave part 110R of the second via insulating layer 110 may be over-etched in a region where the concave part 110R of the second via insulating layer 110 does not overlap the auxiliary patterns 120 and may have an undercut structure. As such, when the first electrode 210 is formed on the undercut structure formed in the concave part 110R of the second via insulating layer 110, the light extraction efficiency of the display device 1 may be reduced.

However, in an embodiment, the etch stop layer ESL is arranged between the auxiliary pattern 120 and the second via insulating layer 110 so that the upper surface of the concave part 110R of the second via insulating layer 110 may be substantially flat. Thus, the first part 211 of the first electrode 210 disposed on the upper surface of the concave part 110R of the second via insulating layer 110 may have a substantially flat upper surface without a bending part. Thus, the light extraction efficiency of the light-emitting clement LED of the display device 1 of the invention may be enhanced.

In an embodiment, the first electrode 210 may include a second part 212 that is disposed on the side surface of the concave part 110R of the second via insulating layer 110 and is inclined. For example, the second part 212 of the first electrode 210 may be an inclined part from the first part 211 of the first electrode 210. That is, as shown in the disclosure, the second via insulating layer 110 has the concave part 110R and the first electrode 210 includes an inclined part (e.g., the second part 212 of the first electrode 210). Thus, viewing angle characteristics such as luminance or color deviation due to a viewing angle may be enhanced.

The first electrode 210 may also include a third part 213 that is disposed on the side surface of the auxiliary pattern 120 and is inclined. For example, the third part 213 of the first electrode 210 may be an inclined part from the first part 211 of the first electrode 210. As the auxiliary pattern 120 is formed on the concave part 110R of the second via insulating layer 110, the first electrode 210 may further include the third part 213 that is an inclined part, in addition to the second part 212. As the display device 1 includes the third part 213 of the first electrode 210, light extraction efficiency toward the front surface of the display device 1 may be enhanced. The second part 212 of the first electrode 210 may be referred to as a first inclined part, and the third part 213 of the first electrode 210 may be referred to as a second inclined part.

In an embodiment, the third part 213 of the first electrode 210 may be connected to the fourth part 214 of the first electrode 210 which is disposed on the upper surface of the auxiliary pattern 120. The third part 213 of the first electrode 210 may be arranged between the first part 211 and the fourth part 214 of the first electrode 210 and may connect the first part 211 and the fourth part 214 of the first electrode 210 to each other.

In an embodiment, as the second via insulating layer 110 has the concave part 110R and the auxiliary pattern 120 are formed on the concave part 110R, the first electrode 210 includes a second part 212 and a third part 213 inclined from the first part 211. Thus, viewing angle characteristics such as luminance or color deviation due to a viewing angle may be enhanced and simultaneously, light extraction efficiency toward the front surface of the display device 1 may also be enhanced. Additionally, the etch stop layer ESL may be arranged between the second via insulating layer 110 and the auxiliary pattern 120, and the upper surface of the concave part 110R of the second via insulating layer 110 may be substantially flat, where the second via insulating layer 110 does not have an undercut structure so that the light extraction efficiency may be prevented from being reduced or may be reduced.

In an embodiment, the first electrode 210 may be a reflective electrode. In this case, the first electrode 210 may include a reflective layer formed of silver (Ag), magnesium (Mg), Al, platinum (Pt), palladium (Pd), gold (Au), nickel (Ni), neodymium (Nd), iridium (Ir), chromium (Cr), and a compound thereof, and a transparent or (semi-)transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the first electrode 210 may have a stack structure of ITO/Ag/ITO.

In an embodiment, a pixel-defining layer 130 may be arranged on the second via insulating layer 110 and may have a pixel opening 130OP that is disposed on the first electrode 210 and that exposes a part of the first electrode 210. The pixel opening 130OP of the pixel-defining layer 130 may overlap the concave part 110R of the second via insulating layer 110. The pixel-defining layer 130 may cover edges of the first electrode 210 and may expose the first part 211, the second part 212, the third part 213, and the fourth part 214 of the first electrode 210. That is, the pixel opening 130OP of the pixel-defining layer 130 may expose the first part 211, the second part 212, the third part 213, and the fourth part 214 of the first electrode 210. The width of the pixel opening 130OP of the pixel-defining layer 130 may be greater than the width of the concave part 110R of the second via insulating layer 110.

In an embodiment, the pixel-defining layer 130 may include an organic insulating material. In another embodiment, the pixel-defining layer 130 may include an inorganic insulating material such as silicon nitride (SiNx) or silicon oxide (SiO₂). In yet another embodiment, the pixel-defining layer 130 may include an inorganic insulating material and an organic insulating material.

In an embodiment, the pixel-defining layer 130 may include a light blocking material. For example, the color of the light blocking material of the pixel-defining layer 130 may be black. The light blocking material may include carbon black, carbon nanotubes, a resin or paste including a black dye, metal particles, such as Ni, Al, Mo and alloys thereof, metal oxide particles, or metal nitride particles. When the pixel-defining layer 130 includes a light blocking material, external light reflection caused by metal structures disposed under the pixel-defining layer 130 may be reduced. However, the invention is not limited thereto. In another embodiment, the pixel-defining layer 130 may not include a light blocking material, but may include a light-transmitting organic insulating material.

In an embodiment, an intermediate layer 220 may be arranged on the first electrode 210. The intermediate layer 220 may be arranged on the pixel-defining layer 130. At least a part of the intermediate layer 220 may be arranged within the pixel opening 130OP of the pixel-defining layer 130. The intermediate layer 220 may include a first common layer 221, a light-emitting layer 222, and a second common layer 223.

In an embodiment, the light-emitting layer 222 may be arranged in the pixel opening 130OP of the pixel-defining layer 130. The light-emitting layer 222 may include an organic material that includes a fluorescent or phosphorescent material capable of emitting blue, green, or red light. The above-described organic material may be a low molecular weight organic material or a polymer organic material. In another embodiment, the light-emitting layer 222 may include an inorganic material including a quantum dot or the like. Specifically, the quantum dot means crystals of a semiconductor compound and may include an arbitrary material that may emit light in various emission wavelengths according to the size of crystals. The quantum dot may include, for example, an III-IV-group semiconductor compound, an II-VI-group semiconductor compound, an III-V-group semiconductor compound, an III-VI-group semiconductor compound, an I-III-VI-group semiconductor compound, an IV-VI-group semiconductor compound, an IV-group element or compound, or an arbitrary combination thereof.

In an embodiment, the first common layer 221 and the second common layer 223 may be arranged below and above the light emitting layer 222, respectively. The first common layer 221 may include, for example, a hole transport layer (HTL) or a HTL and a hole injection layer (HIL). The second common layer 223 may include, for example, an electron transport layer (ETL) or an ETL or an electron injection layer (EIL). In an embodiment, the second common layer 223 may not be provided.

The light-emitting layer 222 may be arranged on each pixel to correspond to the pixel opening 130OP of the pixel-defining layer 130, whereas the first common layer 221 and the second common layer 223 are formed as a single body to entirely cover the substrate 100. In other words, the first common layer 221 and the second common layer 223 may be formed as a single body to cover the display area DA of the substrate 100 entirely

The second electrode 230 may be arranged on the intermediate layer 220, where the second electrode 230 may include a conductive material having a low work function. For example, the second electrode 230 may include a (semi-)transparent layer including Ag, Mg, Al, Pt, Pd, Au, Ni, Nd, Ir, Cr, Li, Ca, ytterbium (Yb) or an alloy thereof. In an example, the second electrode 230 may be AgMg, AgYb or the like. In another embodiment, the second electrode 230 may further include a layer such as ITO, IZO, ZnO or In₂O₃ on the (semi-)transparent layer including the above-described materials. Layers from the first electrode 210 to the second electrode 230 may constitute the light-emitting element LED.

FIG. 5B is a schematic cross-sectional view of a display device taken along a line I-I′ of FIG. 4, according to an embodiment. FIG. 5B illustrates a modified embodiment of the embodiment of FIG. 5A, and redundant descriptions therewith are omitted, and modified parts will be mainly described.

In an embodiment and referring to FIG. 5B, the second via insulating layer 110 may include a lower via insulating layer 110a and an upper via insulating layer 110b. For example, the second via insulating layer 110 having the concave part 110R may be formed by performing a process in which the lower via insulating layer 110a is formed, the upper via insulating layer 110b is formed on the lower via insulating layer 110a and then a part of the upper via insulating layer 110b is removed.

In an embodiment, the upper via insulating layer 110b may expose a part of an upper surface of the lower via insulating layer 110a. The concave part 110R of the second via insulating layer 110 may be defined by the upper surface of the lower via insulating layer 110a and an inner surface of the upper via insulating layer 110b. For example, the upper surface of the lower via insulating layer 110a may be substantially flat, and the inner surface of the upper via insulating layer 110b may be an inclined surface from the upper surface of the lower via insulating layer 110a.

In an embodiment, the auxiliary pattern 120 may be arranged on the upper surface of the lower via insulating layer 110a and may have a side surface inclined from the upper surface of the lower via insulating layer 110a.

The etch stop layer ESL may be arranged between the lower via insulating layer 110a and the auxiliary pattern 120.

The first part 211 of the first electrode 210 may be arranged on the upper surface of the lower via insulating layer 110a and the second part 212 of the first electrode 210 may be arranged on the inner surface of the upper via insulating layer 110b. The third part 213 of the first electrode 210 may be arranged on the side surface of the auxiliary pattern 120, and the fourth part 214 of the first electrode 210 may be arranged on the upper surface of the auxiliary pattern 120.

Each of the lower via insulating layer 110a and the upper via insulating layer 110b may be an organic insulating layer including an organic material. Each of the lower via insulating layer 110a and the upper via insulating layer 110b may include an organic insulating material such as general common-use polymer such as photosensitive polyimide (PSPI), polyimide, polystyrene (PS), polycarbonate (PC), benzocyclobutene (BCB), hexamethyldisiloxane (HMDSO), polymethylmethacrylate (PMMA) or polystyrene (PS), a polymer derivative having a phenol-based group, acryl-based polymer, imide-based polymer, aryl ether-based polymer, amide-based polymer, fluorine-based polymer, p-xylene-based polymer, vinyl alcohol-based polymer, and a blend thereof.

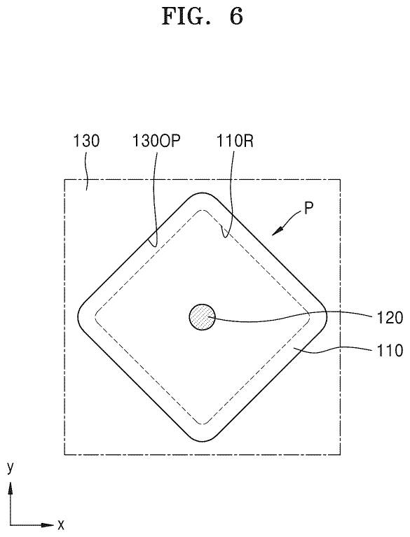

FIG. 6 is a cross-sectional view schematically illustrating the arrangement of the auxiliary pattern 120 in a region corresponding to one pixel P, according to an embodiment. FIG. 6 illustrates a modified embodiment of the embodiment described with reference to FIG. 4, and redundant descriptions therewith are omitted, and modified parts will be mainly described.

In an embodiment and referring to FIG. 6, the auxiliary pattern 120 may have an island pattern shape in a plan view. In FIG. 6, the auxiliary pattern 120 has a circular island pattern shape, but the invention is not limited thereto. For example, the shape of the auxiliary pattern 120 may be variously changed such as a polygonal island pattern shape, a polygonal island pattern shape with round corners, or an elliptical island pattern shape.

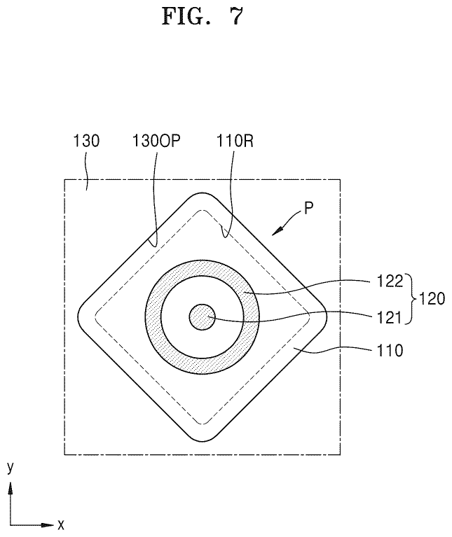

FIG. 7 is a cross-sectional view schematically illustrating the arrangement of the auxiliary pattern 120 in a region corresponding to one pixel P, according to an embodiment. FIG. 7 illustrates a modified embodiment of the embodiment described with reference to FIG. 4, and redundant descriptions therewith are omitted, and modified parts will be mainly described.

In an embodiment and referring to FIG. 7, the auxiliary pattern 120 may include a plurality of patterns. For example, the auxiliary pattern 120 may include a first pattern 121 and a second pattern 122. In FIG. 7, the pattern number of the auxiliary pattern 120 is two. However, the invention is not limited thereto, and the pattern number of the auxiliary pattern 120 may be variously changed.

In an embodiment, a plurality of auxiliary patterns 120 may have an island pattern shape and/or a ring shape in a plan view. For example, the first pattern 121 may have an island pattern shape, and the second pattern 122 may have a ring shape surrounding the first pattern 121. In another embodiment, each of the first pattern 121 and the second pattern 122 may have a ring shape, and the second pattern 122 may surround the first pattern 121.

In FIG. 7, the first pattern 121 has a circular island pattern shape, but the invention is not limited thereto. For example, the shape of the first pattern 121 may be variously changed such as a polygonal island pattern shape, a polygonal island pattern shape with round corners, or an elliptical island pattern shape. The second pattern 122 has a circular ring shape, but the invention is not limited thereto. For example, the shape of the second pattern 122 may be variously changed into a polygonal ring shape, a polygonal ring shape with round corners, an elliptical ring shape, and the like.

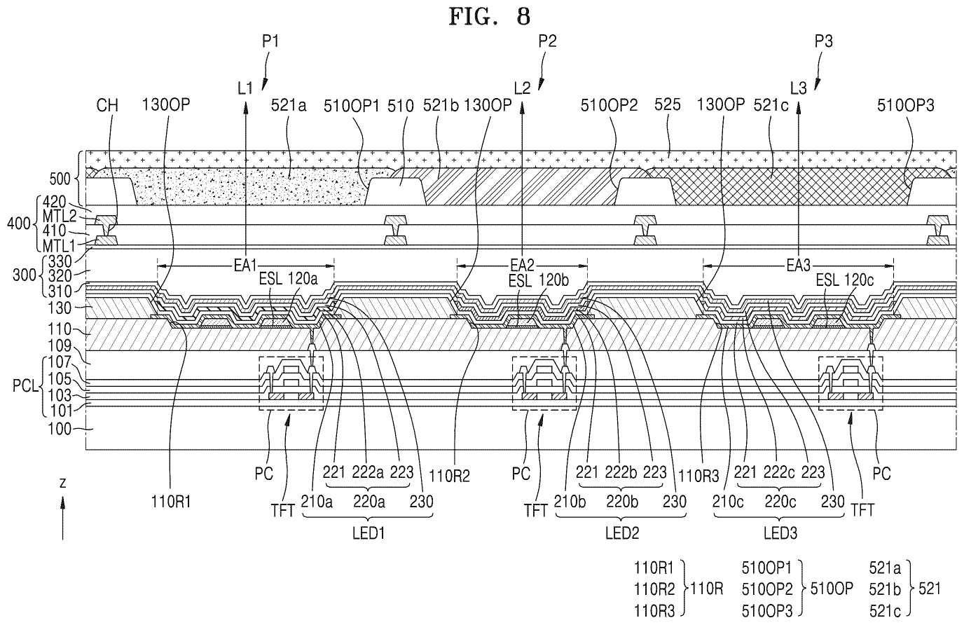

FIG. 8 is a cross-sectional view schematically illustrating the display device 1, according to an embodiment. FIG. 8 is a cross-sectional view illustrating pixels P1, P2, and P3 of the display device 1, where the first pixel P1 may include a first light-emitting element LED1, the second pixel P2 may include a second light-emitting clement LED2, and the third pixel P3 may include a third light-emitting element LED3. Redundant descriptions with the above description will be simplified or omitted.

In an embodiment and referring to FIG. 8, the display device 1 may include a substrate 100, a pixel circuit layer PCL on the substrate 100, a first via insulating layer 109 and a second via insulating layer 110 on the pixel circuit layer PCL, a first light-emitting element LED1, a second light-emitting element LED2, and a third light-emitting element LED3 on the second via insulating layer 110, an encapsulation member 300 on the light-emitting elements LED1, LED2, and LED3, a touch sensing layer 400 on the encapsulation member 300, and an anti-reflection layer 500 on the touch sensing layer 400.

The second via insulating layer 110 may have a plurality of concave parts 110R. For example, the second via insulating layer 110 may include a first concave part 110R1 corresponding to the first emission area EA1 of the first pixel P1, a second concave part 110R2 corresponding to the second emission area EA2 of the second pixel P2, and a third concave part 110R3 corresponding to the third emission area EA3 of the third pixel P3. The plurality of concave parts 110R may be spaced apart from each other. For example, the first concave part 110R1, the second concave part 110R2, and the third concave part 110R3 may be spaced apart from each other. The area of the first concave part 110R1, the second concave part 110R2, and the third concave part 110R3 of the second via insulating layer 110 may be less than the area of the first emission area EA1, the second emission area EA2, and the third emission area EA3.

In an embodiment, each of the upper surface of the first concave part 110R1, the upper surface of the second concave part 110R2, and the upper surface of the third concave part 110R3 of the second via insulating layer 110 may be substantially flat.

In an embodiment, the display device 1 may include a first auxiliary pattern 120a arranged on the first concave part 110R1 of the second via insulating layer 110, a second auxiliary pattern 120b arranged on the second concave part 110R2 of the second via insulating layer 110, and a third auxiliary pattern 120c arranged on the third concave part 110R3 of the second via insulating layer 110. The first auxiliary pattern 120a may be disposed to respond to the first light-emitting clement LED1, the second auxiliary pattern 120b may be disposed to respond to the second light-emitting element LED2, and the third auxiliary pattern 120c may be disposed to correspond to the third light-emitting element LED3.

Each of the auxiliary patterns 120a, 120b, and 120c may have an inclined surface in a cross-section. For example, the first auxiliary pattern 120a may have a side surface inclined from the upper surface of the first concave part 110R1 of the second via insulating layer 110, the second auxiliary pattern 120b may have a side surface inclined from the upper surface of the second concave part 110R2 of the second via insulating layer 110, and the third auxiliary pattern 120c may have a side surface inclined from the upper surface of the third concave part 110R3 of the second via insulating layer 110.

In the embodiment of FIG. 8, the first auxiliary pattern 120a and the third auxiliary pattern 120c have a ring shape, as in the embodiment with reference to FIGS. 4 and 5A, and the second auxiliary pattern 120b has an island pattern shape, as in the embodiment with reference to FIG. 7. That is, the first auxiliary pattern 120a and the third auxiliary pattern 120c, and the second auxiliary pattern 120b may have different shapes from each other. However, the combination of shapes of the auxiliary patterns 120a, 120b, and 120c is not limited thereto. For example, the first auxiliary pattern 120a, the second auxiliary pattern 120b, and the third auxiliary pattern 120c may have different shapes from each other. In another example, the shapes of the first auxiliary pattern 120a, the second auxiliary pattern 120b, and the third auxiliary pattern 120c may be the same. In another embodiment, two auxiliary patterns among the first auxiliary pattern 120a, the second auxiliary pattern 120b, and the third auxiliary pattern 120c may have the same shape, and the other one auxiliary pattern thereof may have a different shape from the shapes of the two auxiliary patterns. For example, in an embodiment, the shapes of the first auxiliary pattern 120a, the second auxiliary pattern 120b, and the third auxiliary pattern 120c may be selected from the shapes of the auxiliary pattern 120 described with reference to FIGS. 4, 6, and 7.

In an embodiment, the auxiliary patterns 120a, 120b, and 120c may include the same material. For example, each of the auxiliary patterns 120a, 120b, and 120c may include a material that may be etched by a dry etching process. Each of the auxiliary patterns 120a, 120b, and 120c may include an inorganic material, for example, silicon nitride (SiNx), silicon oxynitride (SiON), silicon oxide (SiOx) or the like.

In an embodiment, the display device 1 may include the second via insulating layer 110 and etch stop layers ESL disposed between the first auxiliary pattern 120a, the second auxiliary pattern 120b, and the third auxiliary pattern 120c. The etch rates of the etch stop layers ESL and etch rates of the auxiliary patterns 120a, 120b, and 120c may be different from each other.

Shapes of the etch stop layers ESL may respectively corresponding to the auxiliary patterns 120a, 120b, and 120c in a plan view. The etch stop layers ESL may be arranged to overlap the auxiliary patterns 120a, 120b, and 120c, respectively, and may be arranged to be disposed only between the second via insulating layer 110 and the first through third auxiliary patterns 120a, 120b, and 120c. For example, in an embodiment, the auxiliary patterns 120a, 120b, and 120c may cover upper surfaces of the etch stop layers ESL, respectively.

The light-emitting elements LED1, LED2, and LED3 may be arranged on the second via insulating layer 110. The light-emitting elements LED1, LED2, and LED3 may be disposed to correspond to the first concave part 110R1, the second concave part 110R2, and the third concave part 110R3 of the second via insulating layer 110, respectively.

In an embodiment, the first light-emitting clement LED1 may include a 1st-1 electrode 210a, a first common layer 221, a first light-emitting layer 222a, a first intermediate layer 220a including a second common layer 223, and a second electrode 230. The second light-emitting clement LED2 may include a 1st-2 electrode 210b, a first common layer 221, a second light-emitting layer 222b, a second intermediate layer 220b including a second common layer 223, and a second electrode 230. The third light-emitting element LED3 may include a 1st-3 electrode 210c, a first common layer 221, a third light-emitting layer 222c, a third intermediate layer 220c including a second common layer 223, and a second electrode 230.

First electrodes corresponding to neighboring pixels may be arranged to be spaced apart from each other. For example, as shown in FIG. 8, the 1st-1 electrode 210a, the 1st-2 electrode 210b, and the 1st-3 electrode 210c may be spaced apart from each other. The 1st-1 electrode 210a, the 1st-2 electrode 210b, and the 1st-3 electrode 210c may be arranged on the first concave part 110R1, the second concave part 110R2, and the third concave part 110R3, respectively.

The first light-emitting layer 222a of the first light-emitting element LED1, the second light-emitting layer 222b of the second light-emitting element LED2, and the third light-emitting layer 222c of the third light-emitting element LED3 may emit pieces of light having different wavelengths.

In an embodiment, the encapsulation member 300 may be arranged on the light-emitting diodes LED1, LED2, and LED3, where the encapsulation layer 300 may include at least one inorganic layer and at least one organic layer. For example, the encapsulation member 300 may include a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may include an inorganic insulating material such as silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO). The first inorganic encapsulation layer 310 and the second inorganic encapsulation layer 330 may have a single layer or multilayered structure including the above-described materials.

The organic encapsulation layer 320 may be configured to alleviate the internal stress of the first inorganic encapsulation layer 310 and/or the second inorganic encapsulation layer 330 and may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane (HMDSO), acryl-based resin (e.g., polymethylmethacrylate, polyacrylic acid, etc.) or any combination thereof.

The organic encapsulation layer 320 may be formed by applying a material having flowability and including monomers and combining the monomers using heat or light such as ultraviolet rays to react to become polymer. In another embodiment, the organic encapsulation layer 320 may also be formed by applying a polymer material.

In an embodiment, the touch sensing layer 400 may be arranged on the encapsulation member 300, where the touch sensing layer 400 may include a first conductive layer MTL1, a first touch insulating layer 410, a second conductive layer MTL2, and a second touch insulating layer 420. The first conductive layer MTL1 may also be directly arranged on the encapsulation member 300. In this embodiment, the first conductive layer MTL1 may be directly arranged on the second inorganic encapsulation layer 330 of the encapsulation member 300. However, the invention is not limited thereto.

In addition, the touch sensing layer 400 may include an insulating film (not shown) disposed between the first touch electrode layer 410 and the encapsulation member 300. The insulating layer may be disposed on the second inorganic encapsulation layer 330 of the encapsulation member 300 and may planarize a surface on which the first conductive layer MTL1 is disposed. In this case, the first conductive layer MTL1 may be directly disposed on the insulating film. The insulating film may include an inorganic insulating material such as silicon oxide (SiOx), silicon nitride (SiNx), silicon oxynitride (SiON), or the like. In an embodiment, the insulating film may also include an organic insulating material.

In an embodiment, a first touch insulating layer 410 may be disposed on the first conductive layer MTL1 and may include an inorganic material or an organic material. When the first touch insulating layer 410 includes an inorganic material, the first touch insulating layer 410 may include at least one material selected from the group consisting of silicon nitride, aluminum nitride, zirconium nitride, titanium nitride, hafnium nitride, tantalum nitride, silicon oxide, aluminum oxide, titanium oxide, zinc oxide, cerium oxide, and silicon oxynitride. When the first touch insulating layer 410 includes an organic material, the first touch insulating layer 410 may include at least one material selected from the group including an acryl-based resin, methacryl-based resin, polyisophrene, a vinyl-based resin, an epoxy-based resin, a urethane-based resin, a cellulose-based resin, and a parylene-based resin.

In an embodiment, a second conductive layer MTL2 may be disposed on the first touch insulating layer 410 and may serve as a sensor to detect the user's touch input. The first conductive layer MTL1 may serve as a connector connecting the patterned second conductive layer MTL2 in one direction. In another embodiment, both the first conductive layer MTL1 and the second conductive layer MTL2 may serve as a sensor. In this embodiment, the first conductive layer MTL1 and the second conductive layer MTL2 may be electrically connected to each other via a contact hole CH. In this way, as both the first conductive layer MTL1 and the second conductive layer MTL2 serve as a sensor, the resistance of a touch electrode may be reduced, and the user's touch input may be quickly detected.

In an embodiment, the first conductive layer MTL1 and the second conductive layer MTL2 may have a structure through which light emitted from the light-emitting elements LED1, LED2, and LED3 may pass, for example, a mesh structure. In this case, the first conductive layer MTL1 and the second conductive layer MTL2 may be arranged not to overlap the emission areas EA1, EA2, and EA3 of the light-emitting elements LED1, LED2, and LED3, respectively.

The first conductive layer MTL1 and the second conductive layer MTL2 may include a metal layer or a transparent conductive layer. The metal layer may include Mo, Ag, Ti, Cu, Al, and an alloy thereof. The transparent conductive layer may include transparent conductive oxide such as indium tin oxide (ITO), indium zinc oxide (IZO), zinc oxide (ZnO), indium tin zinc oxide (ITZO) or the like. In addition, the transparent conductive layer may include conductive polymer such as poly(3,4-ethylenedioxythiophene)(PEDOT), metal nanowires, carbon nanotubes or graphene.

In an embodiment, a second touch insulating layer 420 may be disposed on the second conductive layer MTL2. The second touch insulating layer 420 may include an inorganic material or an organic material. When the second touch insulating layer 420 includes an inorganic material, the first touch insulating layer 410 may include at least one material selected from the group consisting of silicon nitride, aluminum nitride, zirconium nitride, titanium nitride, hafnium nitride, tantalum nitride, silicon oxide, aluminum oxide, titanium oxide, zinc oxide, cerium oxide, and silicon oxynitride. When the second touch insulating layer 420 includes an organic material, the second touch insulating layer 420 may include at least one material selected from the group including an acryl-based resin, methacryl-based resin, polyisophrene, a vinyl-based resin, an epoxy-based resin, a urethane-based resin, a cellulose-based resin, and a parylene-based resin.

In another embodiment, the touch sensing layer 400 may include a first conductive layer MTL1, a first touch insulating layer 410, a second conductive layer MTL2, and may not include a second touch insulating layer 420. In this embodiment, a light-shielding layer 510 may be provided to cover the second conductive layer MTL2, and a part of the first touch insulating layer 410 may be exposed through an opening 510OP of the light-shielding layer 510.

In an embodiment, an anti-reflection layer 500 may be arranged on the touch sensing layer 400. The anti-reflection layer 500 may include the light-shielding layer 510 and a color filter layer 521. In an embodiment, the anti-reflection layer 500 may further include an overcoat layer 525 disposed on the light-shielding layer 510 and the color filter layer 521.

In an embodiment, the light-shielding layer 510 may include a material that may shield light. For example, the light-shielding layer 510 may include an organic material having a high light absorption rate. The light-shielding layer 510 may include a black pigment or black dye. The light-shielding layer 510 may include a photosensitive organic material, for example, a coloring agent such as a pigment, a dye, or the like.

The light-shielding layer 510 may include an opening 510OP that overlaps each of the emission areas EA1, EA2, and EA3. The opening 510OP of the light-shielding layer 510 may include first through third openings 510OP1, 510OP2, and 510OP3, respectively, which correspond to the light-emitting elements LED1, LED2, and LED3, respectively. The emission areas EA1, EA2, and EA3 may be defined by the pixel opening 130OP of the pixel-defining layer 130. Thus, in an embodiment, the opening 510OP of the light-shielding layer 510 may overlap the pixel opening 130OP of the pixel-defining layer 130, and the width of the opening 510OP of the light-shielding layer 510 may be greater than the width of the pixel opening 130OP of the pixel-defining layer 130.

A body part of the light-shielding layer 510 having the opening 510OP may overlap a body part of the pixel-defining layer 130. For example, the body part of the light-shielding layer 510 may overlap only the body part of the pixel-defining layer 130. The body part of the light-shielding layer 510 may be a part distinguished from the opening 510OP of the light-shielding layer 510 and may mean a part having a certain volume (thickness). Similarly, the body part of the pixel-defining layer 130 may be distinguished from the pixel opening 130OP of the pixel-defining layer 130 and means a part having a certain volume.

In an embodiment, a color filter layer 521 may include different color filters 521a, 521b, and 521c respectively corresponding to the light-emitting elements LED1, LED2, and LED3.

In an embodiment, the color filters 521a, 521b, and 521c may be arranged in the openings 510OP1, 510OP2, and 510OP3, respectively, of the light-shielding layer 510. In an embodiment, the color filters 521a, 521b, and 521c may have colors respectively corresponding to pieces of light emitted from the light-emitting elements LED1, LED2, and LED3. In an embodiment, when the first light-emitting clement LED1 emits red light, the first color filter 521a may be a red color filter, and when the second light-emitting element LED2 emits green light, the second color filter 521b may be a green color filter, and when the third light-emitting element LED3 emits blue light, the third color filter 521c may be a blue color filter. The light-shielding layer 510 may be arranged between neighboring color filters and may be arranged to surround edges of the pixels P1, P2, and P3.

In an embodiment, the overcoat layer 525 may be arranged on the light-shielding layer 510 and the color filter layer 521. The overcoat layer 525 may be a colorless light-transmitting layer having no color in a visible ray band, and may planarize the upper surface of the light-shielding layer 510 and the upper surface of the color filter layer 521. The overcoat layer 525 may include a colorless light-transmitting organic material such as acryl-based resin, and may be covered by a window (not shown). The window may include a transparent (light-emitting) material. For example, the window may include a glass substrate or polymer substrate.

FIGS. 9 through 15 are cross-sectional views illustrating a method of manufacturing a display device, according to an embodiment. FIGS. 9 through 15 illustrate a method of manufacturing a display device in a cross-section corresponding to FIG. 5A.

In an embodiment and referring to FIG. 9, a pixel circuit layer PCL including a thin-film transistor TFT and an insulating layer may be formed on the substrate 100. Next, a first via insulating layer 109 and a second via insulating layer 110 having the concave part 110R may be formed on the pixel circuit layer PCL.

In an embodiment, a buffer layer 101, a semiconductor layer Act disposed on the buffer layer 101, a first gate insulating layer 103 disposed on the semiconductor layer Act, a first capacitor electrode CE1 disposed on the first gate insulating layer 103, a gate electrode GE disposed on the first gate insulating layer 103, a second gate insulating layer 105 disposed on the gate electrode GE, a second capacitor electrode CE2 disposed on the second gate insulating layer 105, an interlayer insulating layer 107 disposed on the second capacitor electrode CE2, and a source electrode SE and a drain electrode DE disposed on the interlayer insulating layer 107 may be sequentially formed on the substrate 100.

The first via insulating layer 109 and the second via insulating layer 110 may be formed on a thin-film transistor TFT. The first via insulating layer 109 may be formed to cover the thin-film transistor TFT on the interlayer insulating layer 107. The first via insulating layer 109 may be formed to cover the source electrode SE and the drain electrode DE. In an embodiment, a connection electrode CM may be disposed on the first via insulating layer 109 and be electrically connected to the thin-film transistor TFT on the first via insulating layer 109.

Next, a concave part 110R of the second via insulating layer 110 may be formed on the first via insulating layer 109. For example, the second via insulating layer 110 having a flat upper surface may be formed, and the concave part 110R of the second via insulating layer 110 may be formed by a process of removing a part of the second via insulating layer 110. For example, a part of the second via insulating layer 110 may be removed to have a groove using a halftone mask, thereby forming a step structure of the second via insulating layer 110. In another example, as shown in FIG. 5B, after a lower via insulating layer 110a and an upper via insulating layer 110b are sequentially formed, a part of the upper via insulating layer 110b may be removed to expose the upper surface of the lower via insulating layer 110a, thereby forming the concave part 110R of the second via insulating layer 110. For example, a part of the upper via insulating layer (see 110b of FIG. 5B) may be removed by a photolithographic process (e.g., exposure and development).

In an embodiment, a via insulating layer (or a planarization insulating layer) for planarizing an upper surface of the pixel circuit PC including the thin-film transistor TFT may be formed with two layers such as the first via insulating layer 109 and the second via insulating layer 110. However, the invention is not limited thereto. For example, the via insulating layer may have a single layer or multi-layered structure with two or more layers.

The first via insulating layer 109 and the second via insulating layer 110 may include an organic insulating material such as general common-use polymer such as photosensitive polyimide (PSPI), polyimide, polystyrene (PS), polycarbonate (PC), benzocyclobutene (BCB), hexamethyldisiloxane (HMDSO), polymethylmethacrylate (PMMA) or polystyrene (PS), a polymer derivative having a phenol-based group, acryl-based polymer, imide-based polymer, aryl ether-based polymer, amide-based polymer, fluorine-based polymer, p-xylene-based polymer, vinyl alcohol-based polymer, and a blend thereof. In an embodiment, in order to provide a flat upper surface, chemical mechanical polishing may be performed on the upper surface of each of the first and second via insulating layers 109 and 110, respectively, after applying an organic material onto the first and second via insulating layers 109 and 110, respectively.

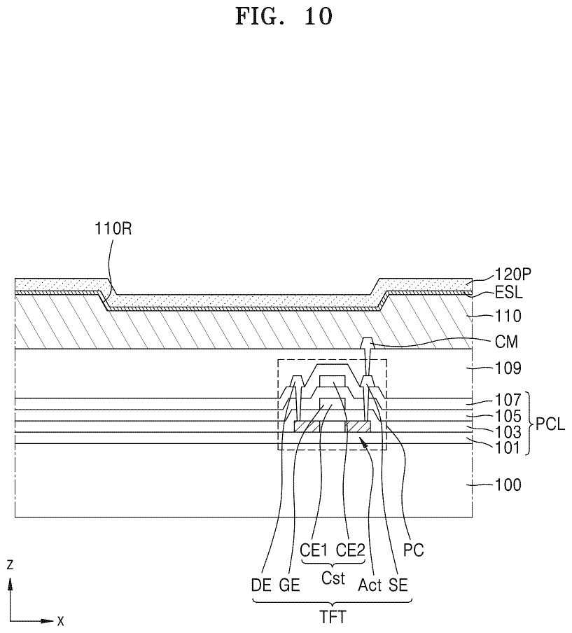

Referring to FIG. 10, an etch stop layer ESL may be formed on the second via insulating layer 110. Next, a preliminary auxiliary pattern 120P may be formed on the etch stop layer ESL. An etch rate of the etch stop layer ESL may be different from an etch rate of the preliminary auxiliary pattern 120P. For example, the etch rate of the etch stop layer ESL may be less than the etch rate of the preliminary auxiliary pattern 120P.

In an embodiment, the etch stop layer ESL may include a material that may be etched using a wet etching process. In an embodiment, the etch stop layer ESL may include a material having a different etch rate from an etch rate of the preliminary auxiliary pattern 120P. For example, when the dry etching process is performed, the etch stop layer ESL may be formed of a material having an etching selectivity with respect to the preliminary auxiliary pattern 120P. For example, the etch stop layer ESL may include IZO, IZGO or ITO.

In an embodiment, the preliminary auxiliary pattern 120 may include a material that may be etched by a dry etching process. For example, the preliminary auxiliary pattern 120P may include an inorganic material, for example, silicon nitride (SiNx), silicon oxynitride (SiON), silicon oxide (SiOx).

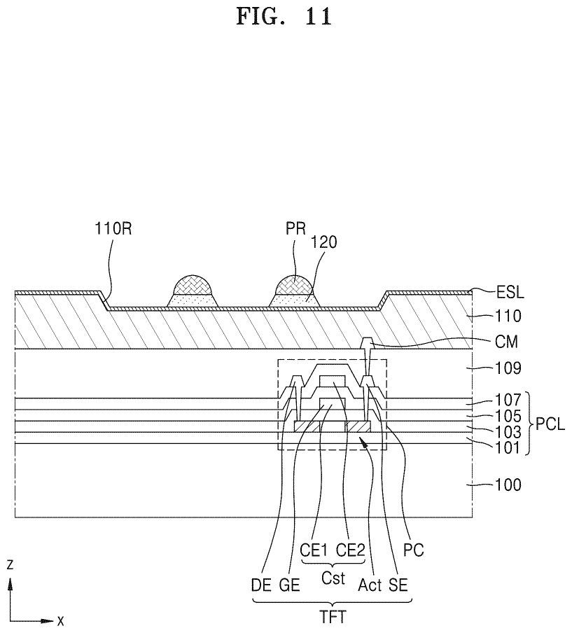

In an embodiment and referring to FIG. 11, a part of the preliminary auxiliary pattern 120P may be etched to form the auxiliary pattern 120 which is disposed on the concave part 110R of the second via insulating layer 110. For example, a photoresist pattern PR may be formed to overlap the concave part 110R of the second via insulating layer 110, and an etching process may be performed using the photoresist pattern PR as an etching mask, thereby forming the auxiliary pattern 120. For example, a process of etching a preliminary auxiliary pattern for forming the auxiliary pattern 120 may be a dry etching process. A part of the preliminary auxiliary pattern 120 is removed by the dry etching process so that the auxiliary pattern 120 may be formed. Thus, the auxiliary pattern 120 may have an inclined surface from the upper surface of the second via insulating layer 110 in a cross-section.

In a comparative example in which the etch stop layer ESL is not formed between the preliminary auxiliary pattern 120P and the second via insulating layer 110, a part of the concave part 110R of the second via insulating layer 110 may be over-etched in an etching process of forming the auxiliary pattern 120. For example, the upper surface of the concave part 110R of the second via insulating layer 110, according to the comparative example, may be over-etched in a region where the concave part 110R of the second via insulating layer 110 does not overlap the auxiliary pattern 120, and may be relatively concave, and may be relatively convex in a region where the concave part 110R of the second via insulating layer 110 overlaps the auxiliary pattern 120, and thus may not be flat. For example, the concave part 110R of the second via insulating layer 110 may be over-etched in a region where the concave part 110R of the second via insulating layer 110 does not overlap the auxiliary pattern 120 and may have an undercut structure.

In an embodiment, the etch stop layer ESL having an etching selectivity with respect to the preliminary auxiliary pattern 120 is arranged between the preliminary auxiliary pattern 120P and the second via insulating layer 110. Thus, even when a process of etching the preliminary auxiliary pattern 120P is performed, the second via insulating layer 110 may not be etched together. Accordingly, an upper surface of the concave part 110R of the second via insulating layer 110 may be substantially flat.

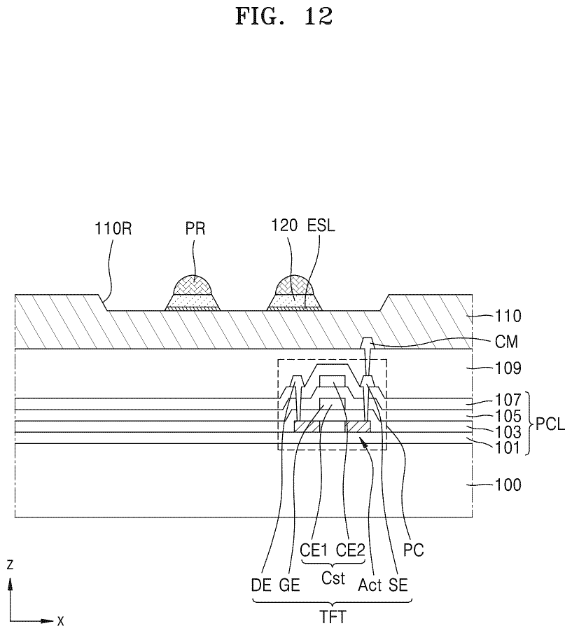

In an embodiment and referring to FIG. 12, a part of the etch stop layer ESL may be etched. A part of the etch stop layer ESL may be etched to have a shape corresponding to the auxiliary pattern 120 in a plan view. Thus, the etch stop layer ESL may be arranged only on the concave part 110R of the second via insulating layer 110. For example, a part of the etch stop layer ESL may be etched by performing an etching process using the photoresist patterns PR and/or the auxiliary pattern 120 as an etching mask. For example, a process of etching a part of the etch stop layer ESL may be a wet etching process.

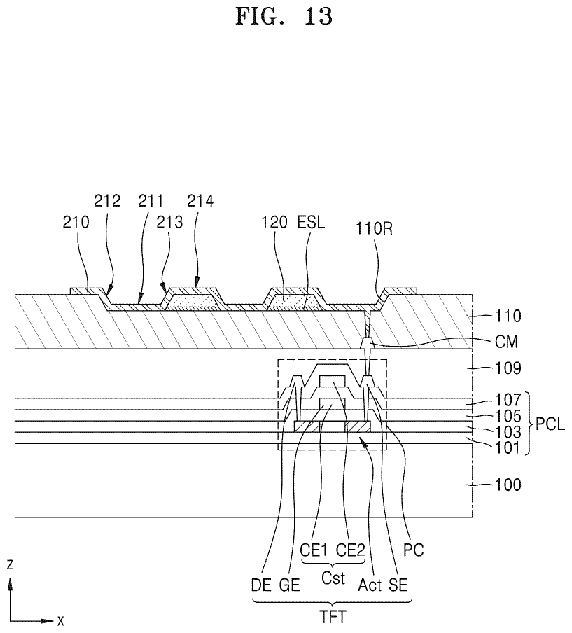

In an embodiment and referring to FIG. 13, a first electrode 210 may be formed on the second via insulating layer 110 and the auxiliary pattern 120. The first electrode 210 may be formed to correspond to the concave part 110R of the second via insulating layer 110. The first electrode 210 may be formed to be arranged on each pixel. That is, first electrodes 210 corresponding to neighboring pixels may be arranged to be spaced apart from each other. For example, the first electrodes 210 may be formed by depositing a conductive material and removing a part of the first electrodes 210 by an etching process.

The first electrode 210 may include a first part 211 disposed on the upper surface of the concave part 110R of the second via insulating layer 110, a second part 212 disposed on the side surface of the concave part 110R of the second via insulating layer 110, a third part 213 disposed on the side surface of the auxiliary pattern 120, and a fourth part 214 disposed on the upper surface of the auxiliary pattern 120.

Since the upper surface of the concave part 110R of the second via insulating layer 110 is substantially flat, the first part 211 of the first electrode 210 arranged on the upper surface of the concave part 110R of the second via insulating layer 110 may have a substantially flat upper surface without a bending part. Thus, the light extraction efficiency of the light-emitting element LED of the display device 1 of the disclosure may be enhanced.

A second part 212 of the first electrode 210 may be arranged on a side surface of the concave part 110R of the second via insulating layer 110 and may be inclined from the first part 211 of the first electrode 210. That is, as, in the disclosure, the second via insulating layer 110 has the concave part 110R, the first electrode 210 includes an inclined part (e.g., the second part 212 of the first electrode 210) and viewing angle characteristics such as luminance or color deviation due to a viewing angle may be enhanced.

The third part 213 of the first electrode 210 may be arranged on the side surface of the auxiliary pattern 120 and may be inclined from the first part 211 of the first electrode 210. As the auxiliary pattern 120 is formed on the concave part 110R of the second via insulating layer 110, the first electrode 210 may further include the third part 213 that is an inclined part, in addition to the second part 212. As the display device 1 includes the third part 213 of the first electrode 210, viewing angle characteristics such as luminance or color deviation due to a viewing angle may be enhanced, and simultaneously, light extraction efficiency toward the front surface of the display device 1 may also be enhanced.

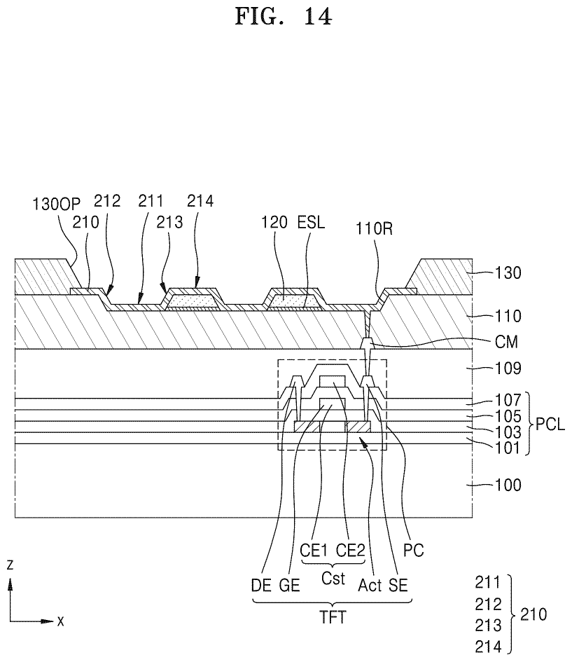

In an embodiment and referring to FIG. 14, a pixel-defining layer 130 may be formed on the first electrode 210. After the pixel-defining layer 130 is formed, a part of the pixel-defining layer 130 may be removed to expose a part of the first electrode 210, thereby forming a pixel opening 130OP. For example, the pixel-defining layer 130 may cover edges of the first electrode 210 and may remove a part of the pixel-defining layer 130 to expose the first part 211, the second part 212, the third part 213, and the fourth part 214 of the first electrode 210, thereby forming a pixel opening 130OP. The pixel opening 130OP of the pixel-defining layer 130 may overlap the concave part 110R of the second via insulating layer 110. The width of the pixel opening 130OP of the pixel-defining layer 130 may be greater than the width of the concave part 110R of the second via insulating layer 110.

In an embodiment, the pixel-defining layer 130 may include an organic insulating material. In an embodiment, the pixel-defining layer 130 may include an inorganic insulating material such as silicon nitride (SiNx) or silicon oxide (SiO₂). In another embodiment, the pixel-defining layer 130 may include an inorganic insulating material and an organic insulating material.

In an embodiment, the pixel-defining layer 130 may include a light blocking material. For example, the color of the light blocking material of the pixel-defining layer 130 may be black. The light blocking material may include carbon black, carbon nanotubes, a resin or paste including a black dye, metal particles, such as Ni, Al, Mo and alloys thereof, metal oxide particles, or metal nitride particles. When the pixel-defining layer 130 includes a light blocking material, external light reflection caused by metal structures disposed under the pixel-defining layer 130 may be reduced. However, the invention is not limited thereto. In another embodiment, the pixel-defining layer 130 may not include a light blocking material, but may include a light-transmitting organic insulating material.

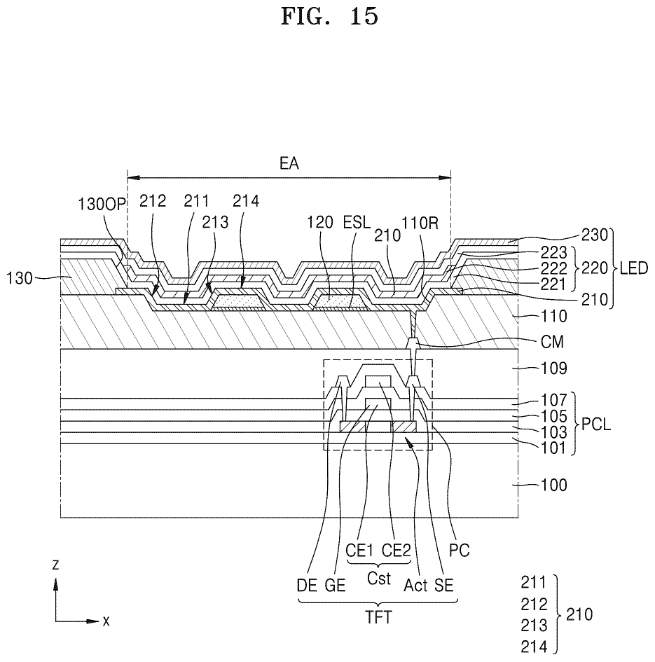

In an embodiment and referring to FIG. 15, an intermediate layer 220 and a second electrode 230 may be sequentially formed on the first electrode 210, thereby forming a light-emitting clement LED. The intermediate layer 220 may include a first common layer 221, a light-emitting layer 222, and a second common layer 223. Each of the first common layer 221, the second common layer 223, and the second electrode 230 may be formed as a single body to cover the substrate 100 entirely. That is, each of the first common layer 221, the second common layer 223, and the second electrode 230 may be formed so that each pixel may share the first common layer 221, the second common layer 223, and the second electrode 230.

In a display device 1, according to an embodiment, luminance deviation and/or color deviation due to a viewing angle can be enhanced, and simultaneously light efficiency can also be enhanced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. 1. A display device comprising:
a substrate;
a pixel circuit layer arranged on the substrate and comprising a thin-film transistor;
a via insulating layer arranged on the pixel circuit layer and having a concave part;
an auxiliary pattern arranged on the concave part;
an etch stop layer arranged between the via insulating layer and the auxiliary pattern; and
a light-emitting element arranged on the via insulating layer.

2. The display device of claim 1, wherein a shape of the etch stop layer corresponds to a shape of the auxiliary pattern in a plan view.

3. The display device of claim 1, wherein, in a cross-sectional view, a side surface of the auxiliary pattern is inclined from an upper surface of the concave part.

4. The display device of claim 1, wherein an upper surface of the concave part is flat.

5. The display device of claim 1, wherein the light-emitting element comprises:
a first electrode disposed on the via insulating layer;
a light-emitting layer disposed on the first electrode; and
a second electrode disposed on the light-emitting layer,
wherein the first electrode comprises a first part which is arranged on an upper surface of the concave part, a second part which is arranged on a side surface of the concave part of the via insulating layer, and a third part which is arranged on a side surface of the auxiliary pattern.

6. The display device of claim 5, wherein each of the second part of the first electrode and the third part of the first electrode is inclined from the first part of the first electrode.

7. The display device of claim 5, further comprising a pixel-defining layer arranged on the first electrode and having a pixel opening that exposes the first part of the first electrode, the second part of the first electrode, and the third part of the first electrode.

8. The display device of claim 1, wherein the auxiliary pattern has an island pattern shape or a ring shape.

9. The display device of claim 1, wherein the etch stop layer and the auxiliary pattern have different etch rates from each other.

10. The display device of claim 1, wherein the auxiliary pattern comprises an inorganic material.

11. A display device comprising:
a substrate;
a pixel circuit layer arranged on the substrate and comprising a thin-film transistor;
a via insulating layer arranged on the pixel circuit layer and having a plurality of concave parts;
auxiliary patterns respectively arranged on the plurality of concave parts;
etch stop layers respectively arranged between the via insulating layer and the auxiliary patterns; and
a first light-emitting element and a second light-emitting element arranged on the via insulating layer and configured to emit pieces of light having different colors, wherein
the first light-emitting element and the second light-emitting element are disposed to correspond to the plurality of concave parts.

12. The display device of claim 11, wherein shapes of the etch stop layers correspond to shapes of the auxiliary patterns in a plan view.

13. The display device of claim 11, wherein an auxiliary pattern disposed to correspond to the first light-emitting element from among the auxiliary patterns and an auxiliary pattern disposed to correspond to the second light-emitting element from among the auxiliary patterns have different shapes from each other.

14. The display device of claim 11, wherein each of the auxiliary patterns has an island pattern shape or a ring shape.

15. The display device of claim 11, wherein the auxiliary patterns comprise an inorganic material.

16. The display device of claim 11, wherein the etch stop layers and the auxiliary patterns have different etch rates from each other.

17. A method of manufacturing a display device, the method comprising:
forming a pixel circuit layer including a thin-film transistor on a substrate and forming a via insulating layer having a concave part on the pixel circuit layer;
forming an etch stop layer on the via insulating layer;
forming a preliminary auxiliary pattern on the etch stop layer;
etching a part of the preliminary auxiliary pattern to form an auxiliary pattern arranged on the concave part;
etching a part of the etch stop layer to have a shape corresponding to a shape of the auxiliary pattern in a plan view; and
forming a light-emitting element on the via insulating layer and the auxiliary pattern, wherein the light-emitting element includes a first electrode, an intermediate layer, and a second electrode.

18. The method of claim 17, wherein etching a part of the preliminary auxiliary pattern includes etching the preliminary auxiliary pattern via a dry etching process.

19. The method of claim 17. wherein etching a part of the preliminary auxiliary pattern includes etching the preliminary auxiliary pattern via a wet etching process.

20. The method of claim 17, wherein an etch rate of the etch stop layer is less than an etch rate of the preliminary auxiliary pattern.
